(19) United States
(12) Patent Application Publication
(10) Pub. No.: US 2005/0079695 A1
(43) Pub. Date: Apr. 14, 2005

(54) Process for fabricating a transistor with a metal gate, and corresponding transistor

(75) Inventors: Nicolas Carriere, Grenoble (FR); Thomas Skotnicki, Crolles Montfort (FR); Brice Tavel, Grenoble (FR)

Correspondence Address: FLEIT, KAIN, GIBBONS, GUTMAN, BONGINI;& BIANCO P.L., ONE BOCA COMMERCE CENTER, 551 NORTHWEST 77TH STREET, SUITE 111, BOCA RATON, FL, 33487, US

(73) Assignees: STMICROELECTRONICS SA, MONTROUGE (FR); COMMISSARIAT A L'ENERGIE ATOMIQUE, PARIS (FR)

(21) Appl. No.: 10/809,942

(22) Filed: Mar. 25, 2004

(30) Foreign Application Priority Data
Mar. 25, 2003 (FR) 03 03647

(51) Int. Cl. H01L 21/3205

(52) U.S. Cl. 438/592

(57) ABSTRACT

A phase of siliciding a transistor includes formation, from a first metal (8), of a first metal silicide (80) on the drain and source regions, while the gate region (30) is protected by a layer of hard mask (40), removal of the hard mask, formation, from a second metal (9), of a second metal silicide (90) on the gate region, while the first metal silicide (80) is protected by the second metal (9), and removal of the second metal (9).

### CROSS-REFERENCE TO RELATED APPLICATION

This application is based upon and claims priority from prior French Patent Application No. 03 03647, filed on Mar. 25, 2003, the entire disclosure of which is herein incorporated by reference.

### BACKGROUND OF THE INVENTION

1. Field of the Invention

The present invention relates in general to integrated circuits and more particularly to the fabrication of transistors with metal gates.

2. Description of the Related Art

By using metal gates it is possible to improve the properties of insulated-gate field-effect transistors (MOS transistors), especially by reducing the gate resistance, while avoiding the gate depletion and boron diffusion problems, and by increasing the threshold voltage of the transistor.

All the current processes for producing metal gates are based on processes of the damascene type, well known to those skilled in the art. In such processes, a chemical-mechanical polishing step is used to protect the active regions (drain and source) of the transistor during metallization of the gate.

It is particularly advantageous in fact, in particular in radio frequency applications, to be able to decouple the siliciding of the active regions from the siliciding of the gate so as to deposit a metal silicide of different thickness on the gate than on the source and drain regions.

However, the chemical-mechanical polishing step is a tricky operation that introduces large variations in the final height of the gates, and has a low yield.

Accordingly, there exists a need for overcoming the disadvantages of the prior art as discussed above.

### SUMMARY OF THE INVENTION

A main object of the invention is to remedy these drawbacks.

An object of the invention is most particularly to produce metal gates by completely siliciding the gate region, while preventing the source and drain regions from being too deeply silicided.

The invention proposes a process for fabricating a transistor with a metal gate, that includes a siliciding phase comprising

the formation, from a first metal, of a first metal silicide on the drain and source regions, while the gate region is protected by a layer of hard mask;
the removal of the hard mask;
the formation, from a second metal, of a second metal silicide in the entire gate region so as to completely silicide the gate region, while the first metal silicide is protected by the second metal; and
the removal of the second metal.

Thus, the invention dispenses with the use of a chemical-mechanical polishing step, making the uptake of siliciding in the active regions impossible (since the second metal does not react with the first metal silicide) and using a layer of hard mask, thereby also making it possible to decouple the siliciding of the active regions from the siliciding of the gate.

In some applications, it is particularly advantageous to make the metal silicide or suicides formed as least resistive as possible. It is therefore advantageous for the siliciding phase to include a final step of annealing the first metal silicide and of the second metal silicide so as to form a first final metal silicide and a second final metal silicide, respectively.

The first metal and the second metal may be identical.

As a variant, the first metal and the second metal may be different.

Thus, the first metal and the second metal may, for example, be chosen from the group formed by titanium (Ti), platinum (Pt), nickel (Ni) and cobalt (Co).

As regards the hard mask, this may be formed, for example, from titanium nitride or from a silicon-germanium alloy (SiₓGe₁₋ₓ).

According to one method for implementing the invention, the formation of the first metal silicide comprises, for example, a deposition of the first metal on the drain and source regions, and a first initial annealing step.

Moreover, the formation of the second metal silicide comprises, for example, a deposition of the second metal on the gate region and on the first metal silicide, and a second initial annealing step.

When the source, drain and gate regions comprise silicon, it is possible to choose cobalt as first metal and as second metal.

In this case, the first initial annealing step and the second initial annealing step are carried out, for example, at a temperature below about 600° C. so as to form CoSi as first metal silicide and second metal silicide.

Moreover, the final annealing step may be carried out at a temperature above about 650° C. so as to form CoSi₂ (less resistive than CoSi) as first final metal silicide and second final metal silicide.

The subject of the invention is also an integrated circuit that includes at least one transistor obtained by the process as defined above.

The subject of the invention is also a process for producing a metal gate of a transistor, which process comprises the complete siliciding of the gate region.

This complete siliciding of the gate region is, for example, decoupled from the siliciding of the source and drain regions.

### BRIEF DESCRIPTION OF THE DRAWINGS

Other advantages and features of the invention will become apparent on examining the detailed description of an entirely non-limiting method of implementing the process according to the invention, illustrated in the appended drawings, in which:

FIGS. 1 to 14 illustrate schematically the principal steps of a method of implementing the process according to the invention, making it possible to obtain a transistor according to the invention.

### DETAILED DESCRIPTION

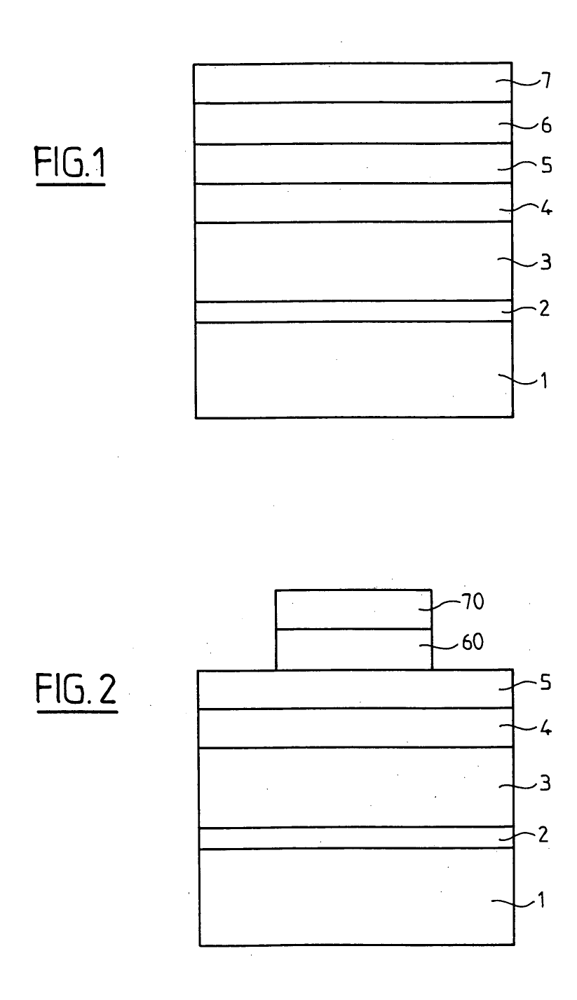

In FIG. 1, the reference 1 denotes a semiconductor substrate, for example made of silicon, it being possible for this substrate to be, optionally, a well incorporated within a silicon wafer.

An oxide layer 2, that will be used to form the gate oxide of the future transistor, is formed on this substrate 1 in a conventional manner known per se, for example by thermal oxidation.

Next, a polysilicon layer 3 is formed, again in a conventional manner known per se, on the oxide layer 2, for example by deposition.

By way of indication, the polysilicon layer, which, as will be seen in the example below, is intended to be silicided in order to form the metal gate of the transistor, has a thickness of 1000 to 1500 Å.

Next, a layer of hard mask 4, for example formed from titanium nitride TiN, and having for example a thickness of the order of 100 Å, is deposited on the polysilicon layer 3.

Next, a silicon dioxide layer which, as will be seen below, will also serve as hard mask during etching of the gate, is formed on the TiN hard mask layer.

Another polysilicon layer 6 is formed on this silicon dioxide layer 5 and this will serve as hard mask during etching of the layer 5.

Finally, a layer of resist 7 is deposited in a conventional manner known per se on the polysilicon layer 6.

Next, the geometry of the gate is defined, in a conventional manner known per se, by a photolithography step. Then, after having exposed and developed the resist, the latter is conventionally etched, the block of resist 70 that remains after etching corresponding to the geometry of the future gate of the transistor (FIG. 2).

The hard mask 70 is also used to etch the polysilicon layer 6 and consequently leave a polysilicon remnant 60.

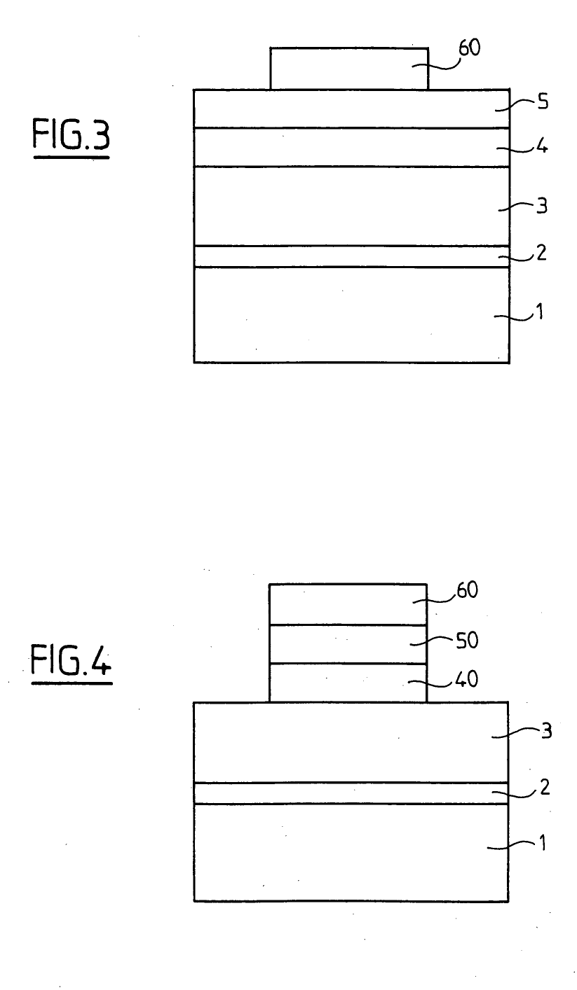

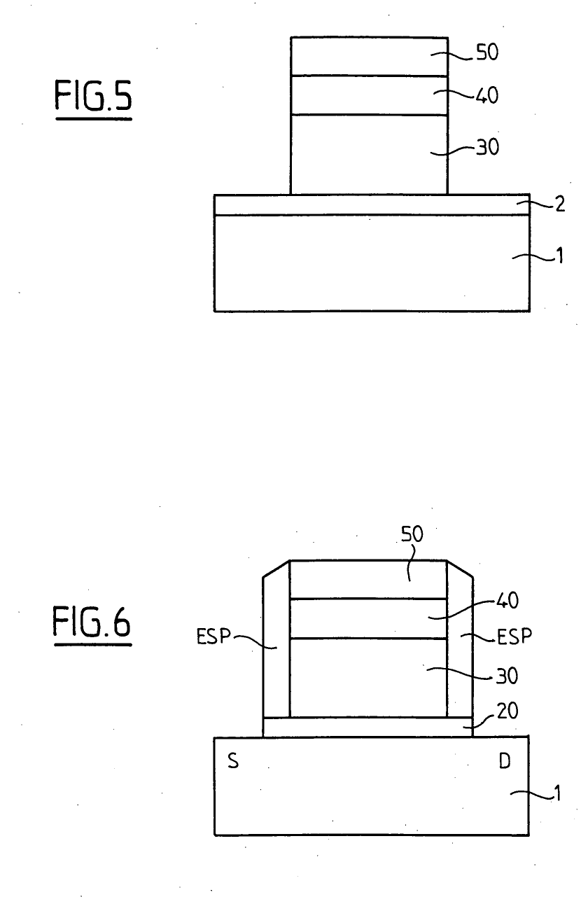

After the resist has been removed, the structure illustrated in FIG. 3 is obtained.

The polysilicon remnant 60 will then be used as hard mask during etching of the oxide layer 5 (FIG. 4).

The etching operation is then continued by conventional anisotropic etching of the TiN hard mask layer 4 and the structure shown in FIG. 4 is then obtained.

After removal of the polysilicon remnant 60 (FIG. 5), the oxide remnant 50 will be used as hard mask to etch the rest of the gate, that is to say the polysilicon layer 3.

After this etching operation, the structure illustrated in FIG. 5 is obtained, which comprises the gate polysilicon 30 surmounted by the TiN hard mask layer 40 that is itself surmounted by the oxide remnant 50.

Next, the continuation of the steps for fabricating the MOS transistor are carried out, by a conventional process known per se, that is to say in particular the formation of lateral isolation regions or spacers ESP on the sidewalls of the gate, and the etching of the oxide layer 2, so as to form the gate oxide 20, and the formation of the source and drain regions S and D by implantation.

It should be noted here that, during these operations, the hard mask layer 40 is protected from the usual cleaning operations by the oxide layer 50 that encapsulates it.

The phase of siliciding the source, drain, and gate regions is then carried out.

In the example described here, the siliciding, that is to say the formation of a metal silicide, is obtained from cobalt.

Since cobalt is incapable of reducing silicon oxide, a deoxidation step is firstly carried out so as to clean the active regions, that is to say the source and drain regions. This deoxidation is carried out, for example using hydrofluoric acid.

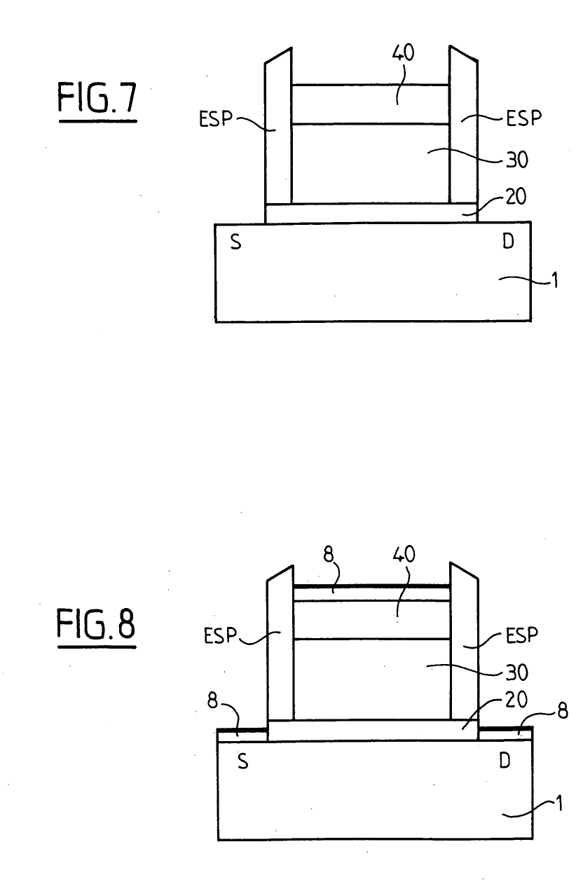

The deoxidation also removes the silicon dioxide remnant 50. Consequently, at this stage, the gate 30 is now protected only by the TiN hard mask layer 40 (FIG. 7).

Next (FIG. 8), a cobalt layer 8 is deposited, for example by plasma vapor deposition (PVD), on the source and drain regions and also on the hard mask layer 40.

Of course, the thickness of the layer 8 is determined according to the thickness of metal silicide that it is desired finally to obtain on the source and drain regions, knowing that when cobalt is used 1 Å of cobalt gives 3.4 Å of silicide.

A first initial annealing step is then carried out, typically at a temperate below 600° C., for example at a temperature of around 530° C.

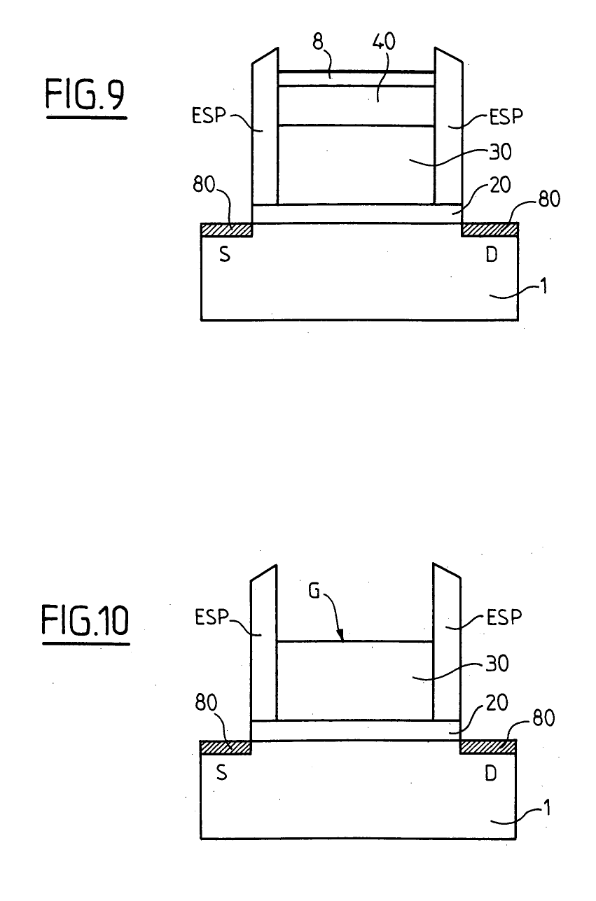

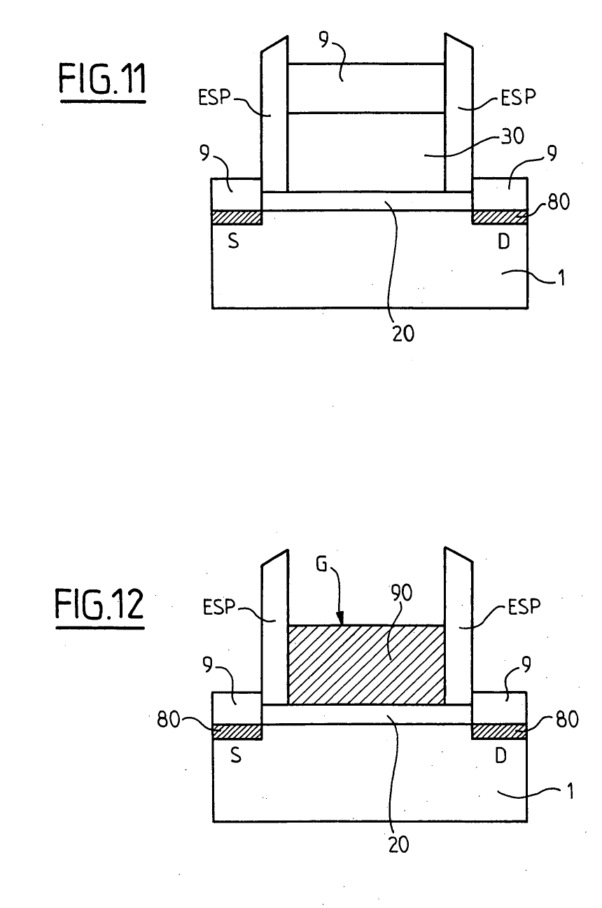

The cobalt 8 then reacts with the silicon of the source and drain regions to form CoSi 80 (FIG. 9).

However, the cobalt 8 that was deposited on the hard mask layer 40 does not react with the polysilicon 30 of the gate since the latter is protected by the hard mask layer 40.

The unreacted cobalt (that is to say the cobalt that was on the hard mask layer 40, and any cobalt remnant that has not reacted with the silicon of the source and drain regions) is then removed (FIG. 10) by a selective removal operation. This selective removal operation is carried out, for example, by wet etching. Wet etching is conventional and known per se—for example, an NH₄OH/H₂O₂/H₂O chemistry or an HCl/H₂₀₂/H₂O chemistry is used.

This wet etching operation also etches the titanium nitride hard mask layer 40 (FIG. 10).

A thick cobalt layer 9 is then deposited on the structure of FIG. 10, the thickness of this cobalt layer 9 being determined so as in this case to silicide the entire gate 30.

Next, a second initial annealing step, similar to the first initial annealing step, is carried out so as to make the cobalt 9 react with the polysilicon 30 of the gate and to form CoSi 90 (FIG. 12).

It should be noted here that cobalt has the particular feature of not reacting with the CoSi 80 of the source and drain regions.

Consequently, the cobalt 9 has protected the metal silicide 80 formed on the source and drain regions during the operation of siliciding the gate. It is therefore possible according to the invention to decouple the siliciding of the source and drain regions from the siliciding of the gate region, so as to be able to silicide the source and drain regions over a small thickness, for example about 300 Å, while completely siliciding the gate, i.e. over about 1000 to 1500 Å.

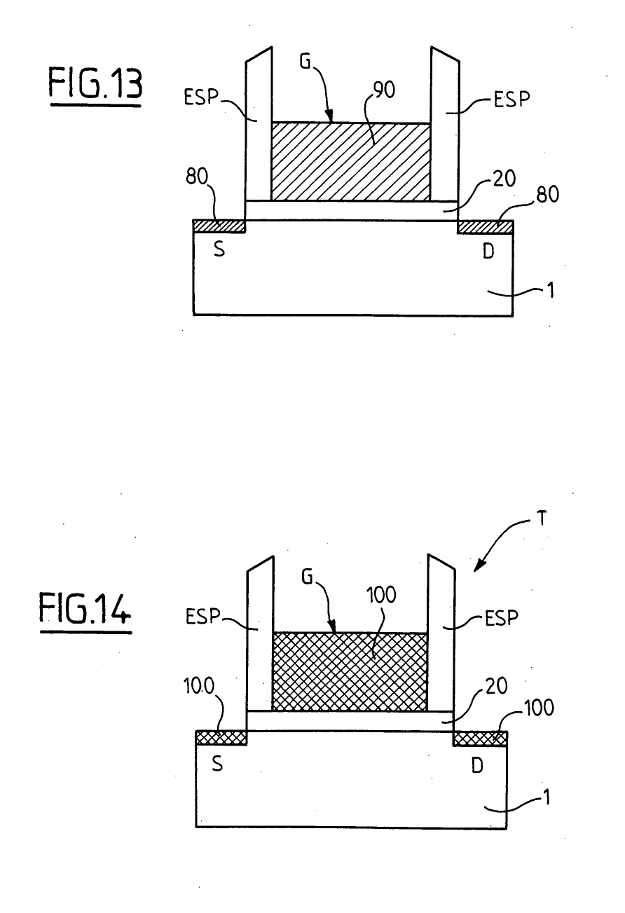

After the cobalt 9 has been removed from the source and drain regions, the structure illustrated in FIG. 13 is therefore obtained.

Since CoSi is a very resistive metal silicide, it is then particularly advantageous, in some applications, to convert this CoSi into CoSi₂, which is much less resistive.

This conversion operation is performed by carrying out a final annealing step, typically at a temperature above 650° C., for example in the region of 830° C.

The transistor T shown in FIG. 14 is then obtained, the source and drain regions and the gate region of which are silicided by CoSi₂ 100.

The fact that the Co/CoSi stack is stable below 600° C. makes any uptake of siliciding on the source and drain active regions impossible, thereby, in combination with the use of a TiN hard mask layer, contributing to decoupling the siliciding of the source and drain active regions from the siliciding of the gate.

In contrast, since the Co/CoSi₂ stack is not stable, it is necessary not to carry out the final siliciding annealing step on the source and drain active regions before cobalt is deposited on the gate.

The invention is not limited to the embodiment and to the method of implementation that have just been described, rather it embraces all variants thereof.

Thus, it is possible to envision two different metals for siliciding the source and drain regions and the gate provided that, of course, the metal B/silicide A stack is stable. In this regard, it will be possible to use cobalt to silicide the gate and nickel to silicide the source and drain active regions.

Furthermore, the hard mask could also be formed from a silicon-germanium alloy.

Moreover, the invention is not limited to the selective siliciding described above for the fabrication of a transistor, but provides, more generally, a siliciding process that includes the formation of a metal silicide on two different semiconductor regions. These two different regions were, in the example of the fabrication of a transistor described above, the source and drain regions on the one hand, and the gate region on the other.

According to a general feature of the invention, for example, the said siliciding phase then comprises:
formation, from a first metal, of a first metal silicide on a first region, while the second region is protected by a layer of hard mask;
removal of the hard mask;
formation, from a second metal, of a second metal suicide on the second region, while the first metal silicide is protected by the second metal; and
removal of the second metal.

While there has been illustrated and described what is presently considered to be a preferred embodiment of the present invention, it will be understood by those of ordinary skill in the art that various other modifications may be made, and equivalents may be substituted, without departing from the true scope of the present invention.

Additionally, many modifications may be made to adapt a particular situation to the teachings of the present invention without departing from the central inventive concept described herein. Furthermore, an embodiment of the present invention may not include all of the features described above. Therefore, it is intended that the present invention not be limited to the particular embodiment disclosed, but that the invention include all embodiments falling within the scope of the appended claims.

1. A method for fabricating a transistor with a metal gate, that includes a siliciding phase comprising:
the formation, from a first metal, of a first metal silicide on the drain and source regions, while the gate region is protected by a layer of hard mask;
the removal of the hard mask;
the formation, from a second metal, of a second metal silicide in the entire gate region so as to completely siliciding the gate region, while the first metal silicide is protected by the second metal; and
the removal of the second metal.

2. The method according to claim 1, wherein the siliciding phase includes a final step of annealing the first metal silicide and of the second metal silicide so as to form a first final metal silicide and a second final metal silicide, respectively.

3. The method according to claim 2, wherein the final annealing step is carried out at a temperature above about 650° C. so as to form CoSi₂ as first final metal silicide and second final metal silicide.

4. The method according to claim 1, wherein the first metal and the second metal are identical.

5. The method according to claim 1, wherein the first metal and the second metal are different.

6. The method according to claim 1, wherein the first metal and the second metal comprise at least one from the group formed by titanium, platinum, nickel, and cobalt.

7. The method according to claim 1, wherein the hard mask is formed from at least one of titanium nitride and a silicon-germanium alloy.

8. The method according to claim 1, wherein the formation of the first metal silicide comprises a deposition of the first metal on the drain and source regions, and a first initial annealing step.

9. The method according to claim 7, wherein the first initial annealing step is carried out at a temperature below about 600° C. so as to form CoSi as first metal silicide and second metal silicide.

10. The method according to claim 1, wherein the formation of the second metal silicide comprises a deposition of the second metal on the gate region and on the first metal silicide, and a second initial annealing step.

11. The method according to claim 10, wherein the second initial annealing step is carried out at a temperature below about 600° C. so as to form CoSi as first metal silicide and second metal silicide.

12. The method according to claim 1, wherein the source, drain and gate regions comprise silicon and in that the first metal and the second metal are cobalt.

13. The method according to claim 12, wherein a first initial annealing step and a second initial annealing step are carried out at a temperature below about 600° C. so as to form CoSi as first metal silicide and second metal silicide.

14. An integrated circuit that includes at least one transistor obtained by a method for fabricating a transistor with a metal gate, the method including a siliciding phase comprising:
the formation, from a first metal, of a first metal silicide on the drain and source regions, while the gate region is protected by a layer of hard mask;
the removal of the hard mask;
the formation, from a second metal, of a second metal silicide in the entire gate region so as to completely siliciding the gate region, while the first metal silicide is protected by the second metal; and
the removal of the second metal.

15. A process for producing a metal gate of a transistor, which process comprises the complete siliciding of the gate region.

16. The process according to claim 15, wherein complete siliciding of the gate region is decoupled from the siliciding of the source and drain regions.
